(19) United States
(12) Patent Application Publication
(10) Pub. No.: US 2026/0288680 A1
(43) Pub. Date: Sep. 24, 2026

(54) METHOD FOR COMPRESSING AND DECOMPRESSING LOG FILES AND AN INFORMATION TECHNOLOGY SYSTEM

(71) Applicant: MERCEDES-BENZ GROUP AG, Stuttgart (DE)

(72) Inventor: Thorsten WILMER, Sindelfingen (DE)

(21) Appl. No.: 19/118,454

(22) PCT Filed: Aug. 28, 2023
(86) PCT No.: PCT/EP2023/073483

§ 371 Date: Apr. 4, 2025

(30) Foreign Application Priority Data
Oct. 5, 2022 (DE) 10 2022 003 682.7

(51) Int. Cl. G06F 16/174; G06F 16/21

(52) U.S. Cl. CPC G06F 16/1744; G06F 16/212

(57) ABSTRACT

Log files are compressed and decompressed using customizable dictionaries. A runtime component is monitored and a source log file is generated. The source log is read into a log encoder. A coding table is initialized from a versioned dictionary or from the source log file. An encoded log file is generated by applying the coding table to the source log file. The encoded log file is read into a log decoder and a version reference to the versioned dictionary used by the log encoder or to the coding table is obtained from the monitoring unit. A dictionary database, providing the dictionary corresponding to the version reference to the log decoder, is accessed and a coding table is initialized from the versioned dictionary by the log decoder. A decoded log file is generated by applying the coding table to the encoded log file.

### BACKGROUND AND SUMMARY OF THE INVENTION

Exemplary embodiments of the invention relate to a method for compressing and decompressing log files when using customizable dictionaries and an information technology system for carrying out the method.

Information technology systems such as PCs or embedded systems consist of hardware and software components. In the development of such systems, it can be necessary to record the behavior of these hardware and software components during operation and to analyze them to check that they are functioning correctly or to detect errors. This also includes so-called “debugging”. The behavior of the corresponding hardware and/or software components is documented in the form of so-called log messages or log files. A log file can be generated by the relevant hardware or software component itself or by a unit monitoring the corresponding component. Subsequent analysis of the corresponding log files is possible with various programs, for example manual analysis using an editor.

Depending on the complexity of the hardware and/or software component to be monitored and the functionality provided by this component, the corresponding log files can vary in size, i.e., take up comparatively little or a lot of storage space on a storage medium. Accordingly, if the data transfer rate is limited, a lot of time is required to transfer the log files between systems and a lot of storage space is required on the respective storage medium. It is therefore desirable to reduce the size of the corresponding log files.

In information technology, various compression and decompression algorithms or methods are known. By way of example, zlib is a free program library for compressing and decompressing data with the deflate algorithm. In contrast to lossy compression, this is lossless compression. The deflate algorithm is one of the so-called dictionary methods, in which the contents of log files, i.e., usually character sequences such as strings, are converted into shorter character strings, taking into account the contents of a respective dictionary. Such a dictionary contains entries for the character sequences that typically and in particular frequently occur in a log file, which define which character strings are used to replace these character sequences. A character sequence such as ‘ABCDE’ can then be replaced by the character string ‘a’, for example. This reduces the content of the log file and reduces the memory requirements accordingly.

Another data compression algorithm is “Brotli”, which is based on a predefined 120 KiB dictionary. However, the disadvantage of this is that only certain predefined character sequences can be reduced in length due to the fixed dictionary.

In contrast to dictionaries with a fixed predetermined size and predetermined contents, customizable dictionaries are also known. A data compression method based on this is known, for example, from DE 43 40 591 C2. The document describes data compression initialization methods that are adaptable to different types of input data and different data structures in order to increase the data compression ratio and reduce the storage space required in a compression/decompression system based on a dictionary. The entries in the corresponding dictionaries are generated depending on the input data to be compressed, i.e., the content of the dictionary is supplemented such that input data originally unknown to the dictionary can also be compressed. The corresponding contents can also be encoded multiple times.

Furthermore, US 2015/0066881 A1 discloses a method for compressing log files that allows the effective collection of data from network nodes. A table-based compression algorithm is used to compress the log files. The underlying table is generated using special training data. This enables the creation of an extensive translation database.

In addition, US 2021/0407220 A1 discloses a system, a method, and a device for managing the collection of data in a vehicle. The publication describes the generation of a log file on the computing unit of a vehicle and the processing of the log file in the vehicle or on a computing unit external to the vehicle.

Exemplary embodiments of the present invention are directed to an improved method for compressing and decompressing log files, with the aid of which the effort involved in processing log files is reduced and yet a comparatively large reduction in memory requirements or file size reduction is possible with different output files.

In a method for compressing and decompressing log files using customizable dictionaries, the following method steps are carried out in accordance with the invention:
monitoring a runtime component and generating a source log file by means of a monitoring unit, wherein the source log file documents the behavior of the runtime component described during the monitoring;
reading the source log file into a log encoder by the monitoring unit;
initializing a coding table from a versioned dictionary or from the source log file by the log encoder;
generating an encoded log file by applying the coding table to the source log file by the log encoder;
transferring the encoded log file from the monitoring unit to a developer unit;
reading the encoded log file into a log decoder by the developer unit and obtaining a version reference to the versioned dictionary used by the log encoder or to the coding table from the monitoring unit;
accessing a dictionary database comprising different versioned dictionaries by the developer unit, providing the dictionary corresponding to the version information to the log decoder, and initializing a coding table from the versioned dictionary by the log decoder; and
generating a decoded log file by applying the coding table to the encoded log file by the log decoder.

A particularly comprehensive data reduction can be achieved with the aid of the method according to the invention, as customizable dictionaries are used. This means that entries can be added to the respective dictionaries in order to be able to compress previously unknown entries from source log files. The processing effort is particularly low thanks to the versioning of the dictionaries. Depending on the content of a respective source log file, which in turn depends on the monitored and/or monitoring hardware and software configuration as well as the functionality provided by the runtime environment, different versions of dictionaries or their underlying coding tables are created, which are thus “tailored” to the respective source log file. To compress the source log files or decompress the compressed source log files, it is then only necessary to derive a coding table from the relevant dictionary and apply this to the respective log file for “translation”. With the help of the version information, clear, reliable, and fast referencing between a respective log file and the dictionary to be applied to this log file or the coding table (for compressing a source log file or for decompressing an encoded log file) is possible. A versioned dictionary and the coding table on which it is based have the same version.

The runtime component is formed by a hardware component and/or a software component. The runtime component can be internal or external to the monitoring unit and is monitored by the monitoring unit. The runtime component can be, for example, a program running on a PC or an embedded system (or a hardware/software component thereof) in a vehicle. The monitoring unit generates the source log file or receives it from the runtime component. The log encoder is part of the monitoring unit and reads in the source log file.

The log encoder or monitoring unit then selects the versioned dictionary or coding table that is provided for encoding the source log file that has been read in. This decision is made based on various boundary conditions, which will be discussed in detail later on.

The dictionary is a binary file, also referred to as “binary” for short. The log encoder initializes a respective coding table from the corresponding versioned dictionary and applies this to the source log file in order to generate the encoded log file. An assignment of which character sequence of the source log file is to be replaced by which character string is thus stored in a respective versioned dictionary. The character string is also a character sequence which is, however, shorter than the original character sequence. The terms “character sequence” and “character string” were therefore chosen here for better understanding. Depending on the content of the source log file, it contains completely different character sequences. This is taken into account by the different versions of the dictionaries, such that only those assignments between character sequences and character strings are contained in a respective versioned dictionary that also mainly occur in a respective source log file. This prevents a dictionary (or the coding table initialized from it/on which it is based) from being applied to a source log file that contains assignments for character sequences that occur only very infrequently or not at all in the source log file. This can also reduce the memory requirements of the dictionaries.

By translating the content of a respective source log file using the coding table (derived from the dictionary), i.e., through the actual compression, the memory requirement of the coded log file is reduced compared to the source log file. This means that the encoded log file can be transferred from the monitoring unit to the developer unit faster than when transferring the (uncompressed) source log file, while using the same transmission bandwidth. This also increases cyber security, as an attacker can only read the encoded log file transmitted in this way if the attacker has access to the dictionary used or the coding table initialized from it.

A dictionary database can be provided by the monitoring unit, the developer unit, and/or also externally. In particular, if the dictionary database is external to the monitoring unit and developer unit and the monitoring unit and developer unit both have read or read and write access to the dictionary database, particularly efficient data transmission between the monitoring unit and developer unit is possible, as only the encoded log file then needs to be transmitted from the monitoring unit to the developer unit and the developer unit receives the corresponding versioned dictionary from the dictionary database via a separate communication channel. This is preferably a communication channel with a comparatively high data transmission rate.

The log decoder has the information about which versioned dictionary it must use in order to be able to initialize the corresponding coding table, which is required to decode the encoded log file. The version information can be transferred in different ways, which will also be discussed later.

The decoded log file substantially or completely corresponds to the source log file. This enables the source log file to be processed on the developer unit, for example to be able to assess the correct functioning of the runtime component or to detect bugs.

An advantageous development of the method provides that the monitoring unit reads in the source log file, generates a coding table depending on the information contained in the source log file, derives a dictionary from the coding table and provides it with a version reference and transfers the versioned dictionary to the dictionary database for storage. This process can be used to create dictionaries customized to a specific source log file.

An appropriately versioned dictionary is therefore suitable for encoding or decoding a source log file generated depending on the hardware and/or software configuration of the runtime component. This is because the content of the source log file will look different depending on the hardware and/or software design of the runtime component or the functionality executed by the runtime component. It is often the case that the same application is run on the same hardware with the same software version under different external boundary conditions. In this case, the same dictionary can be used. If new software is then installed and/or a different functionality is executed, a different version of the dictionary can be used, as the main content of the source log file changes accordingly. Similarly, differently versioned dictionaries can be used if the hardware of the runtime component changes.

The monitoring unit checks which version, i.e., which version reference, is assigned to the respective dictionary when it is generated. In this way, the content of the coding table or the dictionary based on it can be compared with the dictionaries already stored in the dictionary database. If the same content is found, it is one and the same version. However, if no match can be found, it is a new version. Version references can then be assigned according to a predefined pattern, such as consecutive numbering.

Reading in the source log file, generating the coding table and deriving the dictionary from the coding table is carried out by the monitoring unit, in particular after the source log file has been read into the log encoder and before the versioned dictionary is read in and the coding table is initialized by the log encoder. In this way, versioned dictionaries that can be read into the log encoder and initialized there can be generated by the monitoring unit before the source log file itself is encoded. This makes it possible to encode source log files with previously unknown content if no versioned dictionaries are yet available in the dictionary database for such a source log file. Once a corresponding coding table and a corresponding versioned dictionary have been generated from the source log file, the coding table can then be used directly for coding and the generated versioned dictionary can be transferred to the dictionary database for saving.

If, on the other hand, source log files with a familiar pattern, i.e., content, are processed, it is not necessarily necessary to first read and check the content of the source log file each time and, if necessary, generate and store a new coding table and a new versioned dictionary from it. Instead, a versioned dictionary suitable for the respective source log file can be read from the dictionary database. By way of example, a configuration of the monitored runtime component and/or the functionality provided by the runtime component can also be used to determine which versioned dictionary is to be used. A concrete example would be a specific vehicle control unit with a specific firmware that performs a specific task, e.g., an engine control unit that control fuels injection in normal operation. For this use case, the respective source log files will have a certain fixed structure, which can then be assigned to a respective versioned dictionary.

For this purpose, a corresponding dictionary database can also be additionally stored in the monitoring unit.

Versioned dictionaries can be saved as a complete file in the dictionary database or in the form of a differential update. This means that an original version of the dictionary can be saved in its entirety in the dictionary database and versions based on it only contain the content that supplements and/or changes this initial dictionary.

This makes it possible to keep the memory requirements for storing several different versioned dictionaries low.

According to a further advantageous embodiment of the method, the dictionary database is stored on a central computing device. This enables particularly efficient and reliable processing of the log files. The central computing device can be a cloud server, for example. A wide variety of computing systems can have access to the cloud server. By way of example, there can be a plurality of monitoring units that jointly keep the dictionary database held on the central computing device up to date. Similarly, there can be multiple developer units that access the dictionary database on the central computing device in order to load the dictionary that is currently required in each case.

The developer unit can, for example, be a PC with a network or Internet connection to the central computing device. This communication connection is preferably wired. The monitoring unit can be a mobile system that is directly or indirectly connected to the central computing device via a communication module. The communication module can, for example, be connected to the central computing device via mobile radio.

A further advantageous embodiment of the method also provides that the log encoder writes the version information into the encoded log file when generating the encoded log file, depending on the dictionary used. This enables particularly simple and reliable transmission of the version information from the developer unit.

In particular, the version information is written into the encoded log file in an uncoded manner, such that the log decoder or the developer unit can also read out the version information without prior decoding and can load the respective dictionary to be used accordingly.

According to a further advantageous embodiment of the method according to the invention, the developer unit proactively requests the version information from the monitoring unit or reads it from the encoded log file.

Cybersecurity can be improved by proactively requesting the version information. By way of example, a computing unit that wants to decode the log file in question must not only receive the encoded log file and have access to the corresponding dictionary database, but also require information on which dictionary must be used to decode the encoded log file. This means that a corresponding attacker has to fake authorization for the monitoring unit. This is an additional hurdle.

However, the version information can also be written into the encoded log file, making further data transmission between the monitoring unit and developer unit obsolete. This enables even more efficient bandwidth utilization in the transmission stream between the monitoring unit and the developer unit. The version information can generally also be attached to the respective encoded log file in encrypted form. In this way, a suitable key for decrypting the version information is stored on the developer unit.

Preferably, the log encoder continues to use the initialized coding table to generate different encoded log files from different source log files or reinitializes the coding table when reading in a new source log file.

As already explained, the version of the dictionary or the coding table is selected depending on the structure of the respective source log file. If source log files with similar or identical content are to be processed several times in succession, the log encoder can also continue to use the coding table already initialized for this type of source log file. However, if the content or type of the source log file changes, a new coding table must also be initialized or a new version of the dictionary generated accordingly.

Depending on the design and, in particular, the life cycle phase of the monitoring unit or runtime component, it may be the case that only source log files of a known content and type need to be processed. In this case, a particularly efficient process is possible in which the monitoring unit no longer has to read dictionaries from the dictionary database, but instead continues to use an encoding table initialized at an initial point in time. In other words, a respective coding table no longer has to be generated dynamically at the runtime of the monitoring unit, but the initialization of dictionaries on the monitoring unit can be completely omitted, as a pre-initialized coding table is used directly. This means that computing time from a processor of the monitoring unit can be made available for other functions.

In an information technology system having a monitoring unit and a developer unit, in accordance with the invention, the processing unit and the developer unit are set up to carry out a method described above.

Preferably, the monitoring unit and the developer unit are integrated into a common system, in particular in a vehicle. With the aid of the method according to the invention, log files can thus be processed particularly efficiently in the automotive environment. The monitoring unit is therefore a control unit of a vehicle subsystem, a central vehicle computer unit or similar. Accordingly, the runtime component is also formed by a hardware of software module of the vehicle. The developer unit can also be a component of the vehicle. In general, the monitoring unit and developer unit can also be provided on a shared computer unit. However, the monitoring unit and the developer unit can also be designed as two separate computing units, such as two separate vehicle control units. All common road vehicles such as cars, lorries, buses, excavators, tractors and the like, rail vehicles, watercraft or aircraft can be considered as vehicles.

According to a further advantageous embodiment of the information technology system, the monitoring unit and the developer unit are integrated into separate systems or form them, in particular the monitoring unit is integrated into a vehicle and the developer unit is external to the vehicle. By way of example, the developer unit can be designed as a mobile end device such as a laptop or tablet computer, which is connected to the vehicle for communication. By way of example, the mobile end device can be connected to a computing unit of the vehicle via a cable, such as a USB cable or Ethernet cable. Wireless data transmission can also be used, for example WiFi-based, Bluetooth-based or NFC-based wireless data transmission. The developer unit can also be geographically external to the vehicle and, for example, be formed by a desktop computer in an office. A corresponding control unit of the vehicle can send information via a telecommunication module by mobile radio and thus transmit it to the developer unit, in particular via the Internet. Corresponding data transmission is possible between the monitoring unit and the central computing device or the developer unit and the central computing device.

Further advantageous embodiments of the method according to the invention for compressing and decompressing log files using customizable dictionaries emerge from the exemplary embodiment, which is described in more detail below with reference to the figure.

### BRIEF DESCRIPTION OF THE SOLE DRAWING FIGURE

The sole drawing Figure shows a schematic depiction of the components involved in a method according to the invention for compressing and decompressing log files.

### DETAILED DESCRIPTION

The sole drawing Figure illustrates the sequence of a method according to the invention for compressing and decompressing log files using customizable dictionaries 1. A monitoring unit 2 monitors the behavior of a runtime component 2.1 and/or 4. The runtime component 2.1 can be integrated into the monitoring unit 2 or, like the runtime component 4, can be implemented externally for this purpose. The behavior of the runtime component 2.1, 4 is documented by means of a source log file U-Log. The source log file U-Log can be generated by the runtime component 2.1, 4 or also by the monitoring unit 2.

The source log file U-Log is processed by the monitoring unit 2 using a log encoder 2.2. As indicated by a magnifying glass, the monitoring unit 2 checks the content of the source log file U-Log and derives a coding table 5 from this. The coding table 5 describes the rules according to which contents, e.g., character sequences, of the source log file U-Log are to be compressed, i.e., which character strings are to be converted. The coding table 5 can be generated flexibly depending on the content of the source log file U-Log, such that customizable dictionaries 1 can be generated.

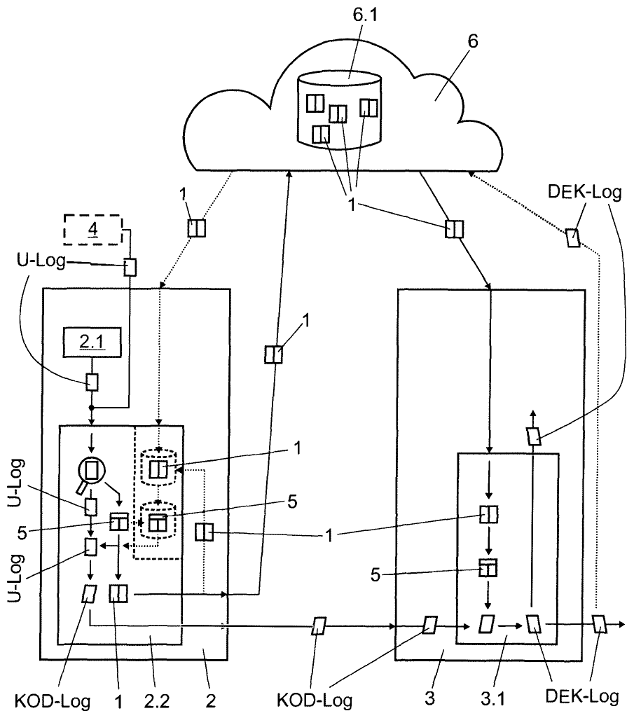

If previously unknown content, i.e., a specific character sequence, is encountered for the first time in the source log file U-Log, new compression rules are created specifically for how this should be compressed, i.e., translated into a shorter character string. The coding table 5 generated in this way is then provided with a version reference by the monitoring unit 2 and transferred to a dictionary database 6.1 for storage in the form of a versioned dictionary 1. In the exemplary embodiment shown in FIG. 1, the dictionary database 6.1 is external to the monitoring unit 2. The dictionary database 6.1 is integrated into a central computing device 6, for example a cloud server. The coding table 5 generated in this way and/or the versioned dictionary 1 generated in this way could also be stored in the monitoring unit 2 for further use, as symbolized by dashed lines.

Either the freshly initialized coding table 5, depending on the content, or a coding table 5 initialized from an already generated versioned dictionary 1 (see the dotted path) is applied to the source log file U-Log (whose content has already been checked). The log encoder 2.2 thus generates an encoded log file KOD-Log from this.

The encoded log file KOD-Log requires less memory than the source log file U-Log, as it contains a smaller number of character strings. The encoded log file KOD-Log is then transferred to a developer unit 3. Due to the reduced memory size, comparatively fast transmission is possible here even with a lower available data transfer rate. The next step is to decode the encoded log file KOD-Log on the developer unit 3 in order to process it further.

In order to do this, the developer unit 3 first requires information on which versioned dictionary 1 can be used for decoding. The developer unit 3 can proactively request this information relating to the corresponding version information from the monitoring unit 2 or, if necessary, also read it from the encoded log file KOD-Log if this information has been appended to it. The developer unit 3 then accesses the dictionary database 6.1 of the central computing device 6 and reads out the appropriately versioned dictionary 1.

The suitably versioned dictionary 1 and the encoded log file KOD-Log are read into a log decoder 3.1. The log decoder 3.1 initializes a corresponding coding table 5 from the respective versioned dictionary 1 and then applies the coding table 5 to the encoded log file KOD-Log in order to generate a decoded log file DEK-Log. The correspondingly decoded log file DEK-Log can then be used to evaluate the system behavior of the runtime component 2.1 or 4. For this purpose, the decoded log file DEK-Log can be processed on the developer unit 3 itself and/or transmitted externally, for example to the central computing device 6.

With the aid of the method according to the invention, particularly efficient processing of log files is possible, since even particularly extensive sources log files U-Log can be compressed in a storage space-efficient manner and the effort required for compression and decompression is low. There are a limited number of possible embodiments of source log files U-Log for which a suitable versioned dictionary 1 is provided. If corresponding hardware and/or software components are further developed, corresponding new versions of the dictionaries 1 are generated and stored in the dictionary database 6.1 for later use. The developer unit 3 then does not have to rebuild a corresponding dictionary 1, but only has to obtain the version information from the monitoring unit 2 in order to read out the appropriate dictionary 1 from the dictionary database 6.1 in each case. The respective dictionary 1 then does not have to be transferred from the monitoring unit 2 to the developer unit 3, which reduces the additional amount of data transferred from the monitoring unit 2 to the developer unit 3. In particular, if the monitoring unit 2 is integrated into a vehicle and encoded log files KOD-Log are sent via a mobile data connection, a low available transmission bandwidth can be utilized efficiently in this way.

Although the invention has been illustrated and described in detail by way of preferred embodiments, the invention is not limited by the examples disclosed, and other variations can be derived from these by the person skilled in the art without leaving the scope of the invention. It is therefore clear that there is a plurality of possible variations. It is also clear that embodiments stated by way of example are only really examples that are not to be seen as limiting the scope, application possibilities or configuration of the invention in any way. In fact, the preceding description and the description of the figures enable the person skilled in the art to implement the exemplary embodiments in concrete manner, wherein, with the knowledge of the disclosed inventive concept, the person skilled in the art is able to undertake various changes, for example, with regard to the functioning or arrangement of individual elements stated in an exemplary embodiment without leaving the scope of the invention, which is defined by the claims and their legal equivalents, such as further explanations in the description.

1-9. (canceled)

10. A method for compressing and decompressing log files using customizable dictionaries, the method comprising:
monitoring, by a monitoring unit, a runtime component,
generating, by the monitoring unit based on the monitoring, a source log file, wherein the source log file documents behavior of the runtime component described during the monitoring;
reading, by the monitoring unit, the source log file into a log encoder;
initializing, by the log encoder, a coding table from a versioned dictionary or from the source log file;
generating, by the log encoder, an encoded log file by applying the coding table to the source log file;
transferring the encoded log file from the monitoring unit to a developer unit;
reading, by the developer unit, the encoded log file into a log decoder and obtaining, by the developer unit, a version reference to the versioned dictionary used by the log encoder or to the coding table from the monitoring unit;
accessing, by the developer unit, a dictionary database comprising different versioned dictionaries;
providing, by the developer unit to the log encoder, a dictionary corresponding to the version reference;
initializing, by the log encoder, a coding table from the versioned dictionary; and
generating, by the log decoder, a decoded log file by applying the coding table to the encoded log file,
wherein the monitoring unit
reads in the source log file,
generates a coding table depending on the information contained in the source log file,
derives a dictionary from the coding table and provides the derived dictionary with a version reference, and
transfers the dictionary and the version reference to the dictionary database for storage.

11. The method of claim 10, wherein the dictionary database is stored on a central computing device.

12. The method of claim 10, wherein the log encoder writes the version reference into the encoded log file when generating the encoded log file depending on the dictionary used.

13. The method of claim 10, wherein the developer unit proactively requests the version reference from the monitoring unit or reads it from the encoded log file.

14. The method of claim 10, wherein the log encoder continues to use the initialized coding table to generate different encoded log files from different source log files or reinitializes the coding table when a new source log file is read in.

15. An information technology system comprising:
a monitoring unit; and
a developer unit,
wherein the monitoring unit is configured to
monitoring a runtime component,
generate, based on the monitoring, a source log file, wherein the source log file documents behavior of the runtime component described during the monitoring,
read the source log file into a log encoder, wherein the log encoder is configured to initialize a coding table from a versioned dictionary or from the source log file and the log encoder is configured to generate an encoded log file by applying the coding table to the source log file, and
transfer the encoded log file to the developer unit,
read in the source log file,
generate a coding table depending on the information contained in the source log file,
derive a dictionary from the coding table and provides the derived dictionary with a version reference, and
transfer the dictionary and the version reference to a dictionary database for storage,
wherein the developer unit is configured to
read the encoded log file into a log decoder and obtain a version reference to the versioned dictionary used by the log encoder or to the coding table from the monitoring unit,
access the dictionary database comprising different versioned dictionaries,
provide a dictionary corresponding to the version reference, wherein the log encoder is configured to initialize a coding table from the versioned dictionary, and the log encoder is configured to generate a decoded log file by applying the coding table to the encoded log file.

16. The information technology system of claim 15, wherein the monitoring unit and the developer unit are integrated into a common system.

17. The information technology system of claim 16, wherein the common system is a vehicle.

18. The information technology system of claim 15, wherein the monitoring unit and the developer unit are integrated into separate systems or form the separate systems.

19. The information technology system of claim 18, wherein the monitoring unit is integrated into a vehicle and the developer unit is external to the vehicle.
